(19) United States
(12) Patent Application Publication
(10) Pub. No.: US 2022/0179316 A1
(43) Pub. Date: Jun. 9, 2022

(54) POLYIMIDE RESIN, POSITIVE-TYPE PHOTOSENSITIVE RESIN COMPOSITION, INSULATING FILM AND SEMICONDUCTOR DEVICE

(71) Applicant: LG CHEM, LTD., Seoul (KR)

(72) Inventors: Jihye KIM, Daejeon (KR); Minyoung LIM, Daejeon (KR); Hyunmin PARK, Daejeon (KR)

(73) Assignee: LG CHEM, LTD., Seoul (KR)

(21) Appl. No.: 17/543,855

(22) Filed: Dec. 7, 2021

(30) Foreign Application Priority Data
Dec. 7, 2020 (KR) 10-2020-0169650

(51) Int. Cl. G03F 7/039; G03F 7/32; G03F 7/38; G03F 7/40; G03F 7/004

(52) U.S. Cl. CPC G03F 7/0392; G03F 7/322; G03F 7/0045; G03F 7/40; G03F 7/38

(57) ABSTRACT

The present specification relates to a polyimide resin, a positive-type photosensitive resin composition, an insulating film and a semiconductor device.

### TECHNICAL FIELD

The present specification claims priority to and the benefits of Korean Patent Application No. 10-2020-0169650, filed with the Korean Intellectual Property Office on Dec. 7, 2020, the entire contents of which are incorporated herein by reference.

The present specification relates to a polyimide resin, a positive-type photosensitive resin composition, an insulating film and a semiconductor device.

### BACKGROUND OF THE INVENTION

Excellent mechanical properties and high heat resistance are required for an interlayer insulating film or surface protection film of a semiconductor device, and a polyimide-based binder resin having excellent properties has been used.

Along with an expansion of application of miniaturization technologies of a FAB (fabrication) process, significant changes have also been taking place in packaging technologies with process technologies for manufacturing high performance, thin, short and small packages.

As the fan-out wafer level package (FO-WLP) market recently grows with changes in the semiconductor post-process technologies, demands for photosensitive polyimide (PID or PSPI) for a redistribution layer (RDL) capable of low temperature curing and having excellent properties have been growing significantly.

A negative-type photosensitive polyimide (PID) has relatively superior mechanical properties, but is difficult to obtain high resolution. A positive-type photosensitive polyimide is capable of obtaining relatively high resolution, but is difficult to satisfy mechanical properties.

Accordingly, development of a photosensitive polyimide (PID) material satisfying both high resolution and mechanical properties has been required.

### BRIEF SUMMARY OF THE INVENTION

The present disclosure is directed to providing a polyimide resin, a positive-type photosensitive resin composition, an insulating film and a semiconductor device.

One embodiment of the present disclosure provides a polyimide resin including, a structure represented by either of the following Chemical Formulae 1 and 2; and a structure represented by any one of the following Chemical Formulae 3 to 5.

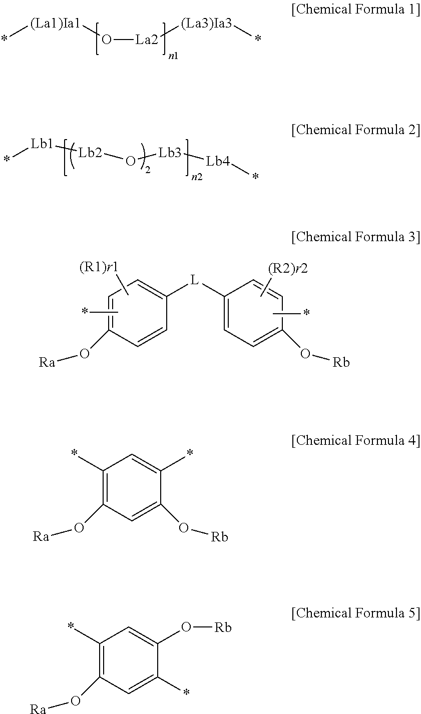

In Chemical Formulae 1 to 5,

[symbol] means a site bonding to other substituents or repeating units,

La1 to La3, Lb1 to Lb4 and L are the same as or different from each other, and each independently a direct bond; a substituted or unsubstituted alkylene group; a substituted or unsubstituted arylene group; —SO₂—; —CO—; or —OCO—,

la1 is 1 or 2, and when la1 is 2, La1s are the same as or different from each other,

la3 is a real number of 0 to 2, and when la3 is 2, La3s are the same as or different from each other,

n1 and n2 are the same as or different from each other and each independently a real number of 1 to 150, and when n1 and n2 are each 2 or greater, structures in the parentheses are the same as or different from each other,

R1 and R2 are the same as or different from each other, and each independently hydrogen; or a substituted or unsubstituted alkyl group,

r1 and r2 are the same as or different from each other and each independently a real number of 0 to 3, and when r1 is 2 or greater, R1s are the same as or different from each other, and when r2 is 2 or greater, R2s are the same as or different from each other,

Ra and Rb are the same as or different from each other, and each independently hydrogen; or a structure represented by the following Chemical Formula a or a structure represented by the following Chemical Formula b,

however, the structure represented by Chemical Formula a or the structure represented by Chemical Formula b is in 1 mol % or greater with respect to a total number of moles of —OH included in the polyimide resin,

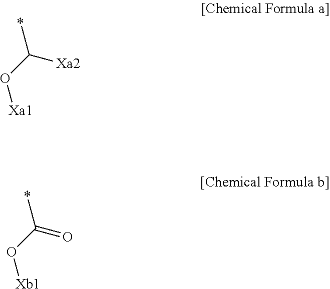

in Chemical Formulae a and b,

[symbol] means a site linked to Chemical Formulae 3 to 5, and

Xa1, Xa2 and Xb1 are the same as or different from each other, and each independently a substituted or unsubstituted alkyl group; or a substituted or unsubstituted cycloalkyl group, or Xa1 and Xa2 bond to each other to form a substituted or unsubstituted ring.

One embodiment of the present disclosure provides a positive-type photosensitive resin composition including a binder resin including the polyimide resin; a photoacid generator; a crosslinking agent; a surfactant; and a solvent.

One embodiment of the present disclosure provides an insulating film including the positive-type photosensitive resin composition or a cured material thereof.

One embodiment of the present disclosure provides a semiconductor device including the insulating film.

### Advantageous Effects

A polyimide resin according to the present specification and a positive-type photosensitive resin composition including the same have excellent elongation, sensitivity and substrate adhesive strength.

### DETAILED DESCRIPTION OF THE INVENTION

In the present specification, a description of a certain member being placed “on” another member includes not only a case of the one member being in contact with the another member but a case of still another member being present between the two member.

In the present specification, a description of a certain part “including” certain constituents means capable of further including other constituents, and does not exclude other constituents unless particularly stated on the contrary.

Hereinafter, the present specification will be described in more detail.

One embodiment of the present specification provides a polyimide resin including a structure represented by any one of the following Chemical Formulae 1 and 2; and a structure represented by any one of the following Chemical Formulae 3 to 5.

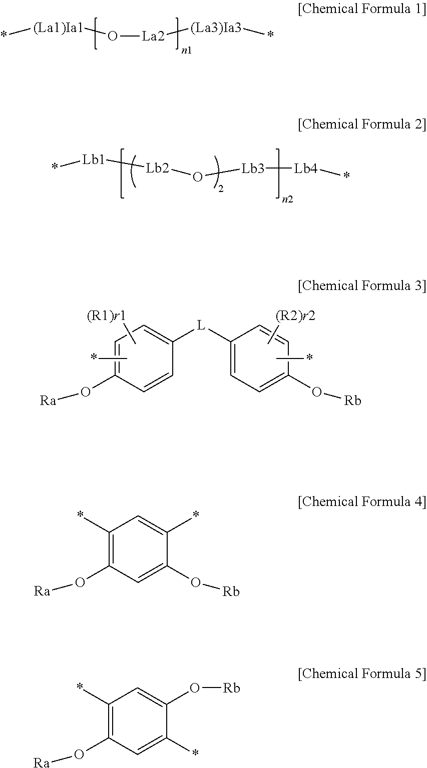

In Chemical Formulae 1 to 5,

[symbol] means a site bonding to other substituents or repeating units,

La1 to La3, Lb1 to Lb4 and L are the same as or different from each other, and each independently a direct bond; a substituted or unsubstituted alkylene group; a substituted or unsubstituted arylene group; —SO₂—; —CO—; or —OCO—,

la1 is 1 or 2, and when la1 is 2, La1s are the same as or different from each other,

la3 is a real number of 0 to 2, and when la3 is 2, La3s are the same as or different from each other,

n1 and n2 are the same as or different from each other and each independently a real number of 1 to 150, and when n1 and n2 are each 2 or greater, structures in the parentheses are the same as or different from each other,

R1 and R2 are the same as or different from each other, and each independently hydrogen; or a substituted or unsubstituted alkyl group,

r1 and r2 are the same as or different from each other and each independently a real number of 0 to 3, and when r1 is 2 or greater, R1s are the same as or different from each other, and when r2 is 2 or greater, R2s are the same as or different from each other,

Ra and Rb are the same as or different from each other, and each independently hydrogen; or a structure represented by the following Chemical Formula a or a structure represented by the following Chemical Formula b,

however, the structure represented by Chemical Formula a or the structure represented by Chemical Formula b is in 1 mol % or greater with respect to a total number of moles of —OH included in the polyimide resin,

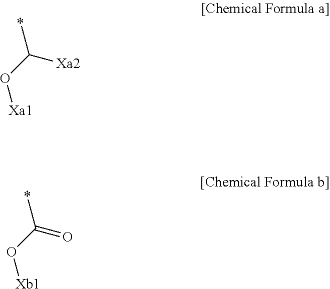

in Chemical Formulae a and b,

[symbol] means a site linked to Chemical Formulae 3 to 5, and

Xa1, Xa2 and Xb1 are the same as or different from each other, and each independently a substituted or unsubstituted alkyl group; or a substituted or unsubstituted cycloalkyl group, or Xa1 and Xa2 bond to each other to form a substituted or unsubstituted ring.

The polyimide resin according to the present specification includes a flexible chain, and introduces a protection group having alkali-soluble properties by an acid. Since the polyimide resin includes a protection group, a positive-type photosensitive resin composition including the same has more superior resolution compared to a photosensitive resin composition using a photoacid generator (PAC; photoactive compound) generally used in the art. In addition, the positive-type photosensitive resin composition according to the present specification is capable of providing a photosensitive resin composition with superior sensitivity even when using a small amount of photoacid generator.

Specifically, the polyimide resin according to the present specification has hydrophilicity by including a flexible chain including an ester or ether group, and has enhanced substrate adhesive strength by providing meltability at a high temperature (approximately 100° C. to 200° C.). In addition, elongation is enhanced since the flexible chain provides flexibility to the polyimide resin, which suppresses wafer bending. In addition, a glass transition temperature (Tg) of the polyimide resin is lowered helping with diffusion of the photoacid generator included in the positive-type photosensitive resin composition, which improves resolution.

In the present specification, [symbol] may mean a site bonding to other substituents or bonding sites, and may mean a site bonding to a main chain of a polymer of the present specification.

The “polymer” in the present specification means a compound formed by repeating a repeating unit (basic unit). The polymer may be expressed as a polymer or a compound formed with a polymer.

In the present specification, examples of the substituents are described below, however, the substituents are not limited thereto.

In the present specification, the term “substituted or unsubstituted” means being substituted with one or more substituents selected from the group including deuterium; a halogen group; a nitrile group; a nitro group; a hydroxyl group; —COOH; an alkoxy group; an alkyl group; a cycloalkyl group; an alkenyl group; a cycloalkenyl group; an aryl group; a heteroaryl group; and a heterocyclic group including one or more of N, O, S and P atoms, or having no substituents.

In the present specification, examples of the halogen group may include fluorine, chlorine, bromine or iodine.

In the present specification, the alkoxy group may be linear or branched, and although not particularly limited thereto, the number of carbon atoms may be from 1 to 30, may be specifically from 1 to 20, and may be more specifically from 1 to 10.

In the present specification, the alkyl group may be linear or branched, and although not particularly limited thereto, the number of carbon atoms is preferably from 1 to 60. According to one embodiment, the number of carbon atoms of the alkyl group is from 1 to 30. According to another embodiment, the number of carbon atoms of the alkyl group is from 1 to 20. According to another embodiment, the number of carbon atoms of the alkyl group is from 1 to 10. Specific examples of the alkyl group may include a methyl group, an ethyl group, an n-propyl group, an isopropyl group, an n-butyl group, an isobutyl group, a tert-butyl group, an n-pentyl group, an n-hexyl group, an n-heptyl group, an n-octyl group and the like, but are not limited thereto. In the present specification, the cycloalkyl group is not particularly limited, but preferably has 3 to 30 carbon atoms, and is particularly preferably a cyclopentyl group or a cyclohexyl group. However, the cycloalkyl group is not limited thereto.

In the present specification, the descriptions on the alkyl group provided above are applied to the alkylene group except that the alkylene group is divalent.

In the present specification, the cycloalkyl group is not particularly limited, but preferably has 3 to 60 carbon atoms, and according to one embodiment, the number of carbon atoms of the cycloalkyl group is from 3 to 30. According to another embodiment, the number of carbon atoms of the cycloalkyl group is from 3 to 20. According to another embodiment, the number of carbon atoms of the cycloalkyl group is from 3 to 6. Specific examples thereof may include a cyclopropyl group, a cyclobutyl group, a cyclopentyl group, a cyclohexyl group, a cycloheptyl group, a cyclooctyl group and the like, but are not limited thereto.

In the present specification, the alkenyl group may be linear or branched, and although not particularly limited thereto, the number of carbon atoms is preferably from 2 to 60. According to one embodiment, the number of carbon atoms of the alkenyl group is from 2 to 30. According to another embodiment, the number of carbon atoms of the alkenyl group is from 2 to 20. According to another embodiment, the number of carbon atoms of the alkenyl group is from 2 to 10. Specific examples of the alkenyl group may preferably include an aryl group-substituted alkenyl group such as a stilbenyl group and a styrenyl group, but are not limited thereto.

In the present specification, the cycloalkenyl group is not particularly limited, but preferably has 3 to 60 carbon atoms, and according to one embodiment, the number of carbon atoms of the cycloalkenyl group is from 3 to 30. According to another embodiment, the number of carbon atoms of the cycloalkenyl group is from 3 to 20. According to another embodiment, the number of carbon atoms of the cycloalkenyl group is from 3 to 6. Examples of the cycloalkenyl group may include a cyclopentenyl group and a cyclohexenyl group, but are not limited thereto.

In the present specification, the aryl group is not particularly limited, but preferably has 6 to 60 carbon atoms, and may be a monocyclic aryl group or a polycyclic aryl group. According to one embodiment, the number of carbon atoms of the aryl group is from 6 to 30. According to one embodiment, the number of carbon atoms of the aryl group is from 6 to 20. When the aryl group is a monocyclic aryl group, examples thereof may include a phenyl group, a biphenyl group, a terphenyl group and the like, but are not limited thereto. When the aryl group is a polycyclic aryl group, examples thereof may include a naphthyl group, an anthracenyl group, an indenyl group, a phenanthrenyl group, a pyrenyl group, a perylenyl group, a triphenyl group, a chrysenyl group, a fluorenyl group and the like, but are not limited thereto.

In the present specification, the descriptions on the aryl group provided above are applied to the arylene group except that the arylene group is divalent.

In the present specification, the heterocyclic group is a heterocyclic group including 0, N or S as a heteroatom, and although not particularly limited thereto, the number of carbon atoms is from 2 to 30, and specifically from 2 to 20. Examples of the heterocyclic group may include a thiophene group, a furan group, a pyrrole group, an imidazole group, a thiazole group, an oxazole group, an oxadiazole group, a triazole group, a pyridyl group, a bipyridyl group, a triazine group, an acridyl group, a pyridazine group, a quinolinyl group, an isoquinoline group, an indole group, a carbazole group, a benzoxazole group, a benzimidazole group, a benzothiazole group, a benzocarbazole group, a benzothiophene group, a dibenzothiophene group, a benzofuranyl group, a dibenzofuran group, tetrahydropyran and the like, but are not limited thereto. Preferably, the heterocyclic group is tetrahydropyran.

In the present specification, the descriptions on the heterocyclic group provided may be applied to the heteroaryl group except that the heteroaryl group is aromatic.

In the present specification, the aromatic ring may be an aryl group or a heteroaryl group, and as the aryl group or the heteroaryl group, the descriptions provided above may be applied. The aliphatic ring may mean a ring that is not the aromatic ring.

In one embodiment of the present specification, La1 to La3, Lb1 to Lb4 and L are the same as or different from each other, and each independently a direct bond; a substituted or unsubstituted alkylene group having 1 to 30 carbon atoms; a substituted or unsubstituted arylene group having 6 to 30 carbon atoms; —SO₂—; —CO—; or —OCO—.

In one embodiment of the present specification, La1 to La3, Lb1 to Lb4 and L are the same as or different from each other, and each independently a direct bond; a substituted or unsubstituted alkylene group having 1 to 20 carbon atoms; a substituted or unsubstituted arylene group having 6 to 20 carbon atoms; —SO₂—; —CO—; or —OCO—.

In one embodiment of the present specification, La1 to La3, Lb1 to Lb4 and L are the same as or different from each other, and each independently a direct bond; a substituted or unsubstituted alkylene group having 1 to 10 carbon atoms; a substituted or unsubstituted arylene group having 6 to 12 carbon atoms; —SO₂—; —CO—; or —OCO—.

In one embodiment of the present specification, R1 and R2 are the same as or different from each other, and each independently hydrogen; or a substituted or unsubstituted alkyl group having 1 to 30 carbon atoms.

In one embodiment of the present specification, R1 and R2 are the same as or different from each other, and each independently hydrogen; or a substituted or unsubstituted alkyl group having 1 to 20 carbon atoms.

In one embodiment of the present specification, R1 and R2 are the same as or different from each other, and each independently hydrogen; or a substituted or unsubstituted alkyl group having 1 to 10 carbon atoms.

In one embodiment of the present specification, Ra and Rb are the same as or different from each other, and each independently hydrogen; or the structure represented by Chemical Formula a or the structure represented by Chemical Formula b.

In one embodiment of the present specification, Xa1, Xa2 and Xb1 are the same as or different from each other, and each independently a substituted or unsubstituted alkyl group having 1 to 30 carbon atoms; or a substituted or unsubstituted cycloalkyl group having 3 to 30 carbon atoms, or Xa1 and Xa2 bond to each other to form a substituted or unsubstituted heteroring having 2 to 30 carbon atoms.

In one embodiment of the present specification, Xa1, Xa2 and Xb1 are the same as or different from each other, and each independently a substituted or unsubstituted alkyl group having 1 to 20 carbon atoms; or a substituted or unsubstituted cycloalkyl group having 3 to 20 carbon atoms, or Xa1 and Xa2 bond to each other to form a substituted or unsubstituted heteroring having 2 to 20 carbon atoms.

In one embodiment of the present specification, Xa1, Xa2 and Xb1 are the same as or different from each other, and each independently a substituted or unsubstituted alkyl group having 1 to 10 carbon atoms; or a substituted or unsubstituted cycloalkyl group having 3 to 10 carbon atoms, or Xa1 and Xa2 bond to each other to form a substituted or unsubstituted heteroring having 2 to 10 carbon atoms.

In one embodiment of the present specification, Chemical Formulae 3 to 5 may be represented by any one of the following chemical formulae.

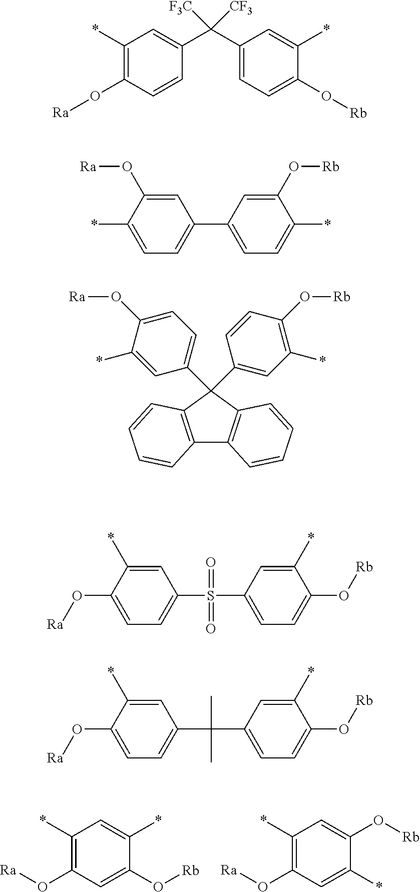

In the chemical formulae, Ra and Rb have the same definitions as in Chemical Formulae 3 to 5.

In one embodiment of the present specification, the polyimide resin further includes a structure represented by the following Chemical Formula E.

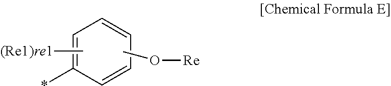

In Chemical Formula E,

[symbol] means a site bonding to other substituents or repeating units,

Re1 is hydrogen; or a substituted or unsubstituted alkyl group,

re1 is a real number of 0 to 4, and when re1 is 2 or greater, Re1s are the same as or different from each other, and

Re is hydrogen; or the structure represented by Chemical Formula a or the structure represented by Chemical Formula b.

In one embodiment of the present specification, the structure represented by Chemical Formula E may be an end group of the polyimide resin.

In one embodiment of the present specification, Re1 is hydrogen; or a substituted or unsubstituted alkyl group having 1 to 30 carbon atoms.

In one embodiment of the present specification, Re1 is hydrogen; or a substituted or unsubstituted alkyl group having 1 to 20 carbon atoms.

In one embodiment of the present specification, Re1 is hydrogen; or a substituted or unsubstituted alkyl group having 1 to 10 carbon atoms.

In one embodiment of the present specification, Re1 is hydrogen.

In one embodiment of the present specification, Re is hydrogen.

In one embodiment of the present specification, Re is the structure represented by Chemical Formula a.

In one embodiment of the present specification, Re is the structure represented by Chemical Formula b.

In one embodiment of the present specification, Chemical Formula a may be represented by any one of the following chemical formulae.

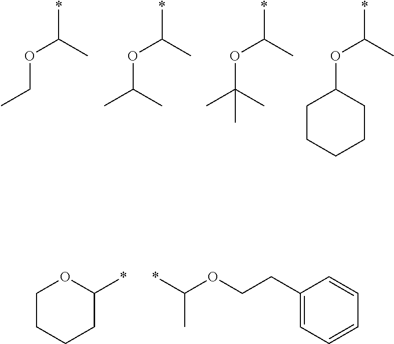

In the chemical formulae, [symbol] means a site bonding to other substituents or repeating units.

In one embodiment of the present specification, Chemical Formula b may be represented by the following chemical formula.

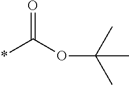 [SMILES: *C(=O)OC(C)(C)C]

In the chemical formula, [symbol] means a site bonding to other substituents or repeating units.

In one embodiment of the present specification, Chemical Formula 1 is represented by the following Chemical Formulae 1-1 to 1-3.

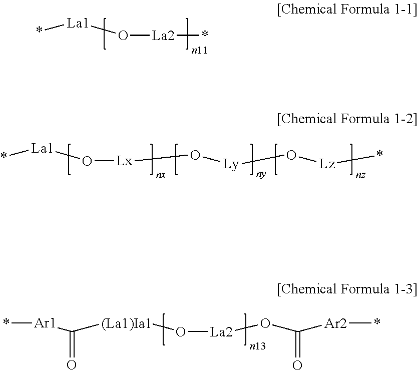

In Chemical Formulae 1-1 to 1-3,

[symbol] means a site bonding to other substituents or repeating units,

La1, La2 and la1 have the same definitions as in Chemical Formula 1,

Lx, Ly and Lz are the same as or different from each other, and each independently a substituted or unsubstituted alkylene group,

Ar1 and Ar2 are the same as or different from each other, and each independently a substituted or unsubstituted arylene group,

n11 is a real number of 1 to 30,

nx, ny and nz are each independently a real number of 1 to 50, and

n13 is a real number of 1 to 30.

When n11, nx, ny, nz and n13 satisfy the above-described ranges, the polyimide resin has flexibility by having a flexible chain, and elongation may be enhanced.

In one embodiment of the present specification, Lx, Ly and Lz are the same as or different from each other, and each independently a substituted or unsubstituted alkylene group having 1 to 30 carbon atoms.

In one embodiment of the present specification, Lx, Ly and Lz are the same as or different from each other, and each independently a substituted or unsubstituted alkylene group having 1 to 20 carbon atoms.

In one embodiment of the present specification, Lx, Ly and Lz are the same as or different from each other, and each independently a substituted or unsubstituted alkylene group having 1 to 10 carbon atoms.

In one embodiment of the present specification, Ar1 and Ar2 are the same as or different from each other, and each independently a substituted or unsubstituted arylene group having 6 to 30 carbon atoms.

In one embodiment of the present specification, Ar1 and Ar2 are the same as or different from each other, and each independently a substituted or unsubstituted arylene group having 6 to 20 carbon atoms.

In one embodiment of the present specification, Ar1 and Ar2 are the same as or different from each other, and each independently a substituted or unsubstituted arylene group having 6 to 12 carbon atoms.

In one embodiment of the present specification, the polyimide resin further includes any one of structures represented by the following Chemical Formulae A-1 to A-4.

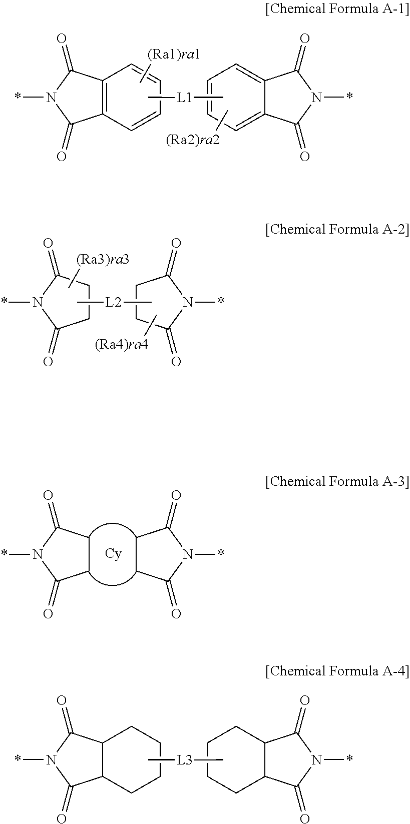

In Chemical Formulae A-1 to A-4,

[symbol] means a site bonding to other substituents or repeating units,

L1 to L3 are the same as or different from each other, and each independently a direct bond; a substituted or unsubstituted alkylene group; a substituted or unsubstituted arylene group; —O—; —CO—; —S—; —COO-L′—OCO—; or —O—(L″)m-O—,

L′ and L″ are the same as or different from each other, and each independently a substituted or unsubstituted alkylene group; or a substituted or unsubstituted arylene group,

m is a real number of 1 to 5, and when m is 2 or greater, L″s are the same as or different from each other,

Ra1 to Ra4 are the same as or different from each other, and each independently hydrogen; or a substituted or unsubstituted alkyl group,

ra1 to ra4 are the same as or different from each other and each independently a real number of 0 to 3, and when ra1 is 2 or greater, Ra1s are the same as or different from each other, when ra2 is 2 or greater, Ra2s are the same as or different from each other, when ra3 is 2 or greater, Ra3s are the same as or different from each other, and when ra4 is 2 or greater, Ra4s are the same as or different from each other, and

Cy means a substituted or unsubstituted aliphatic ring or aromatic ring.

In one embodiment of the present specification, any one of Chemical Formulae A-1 to A-4 may be derived from any one of the following chemical formulae.

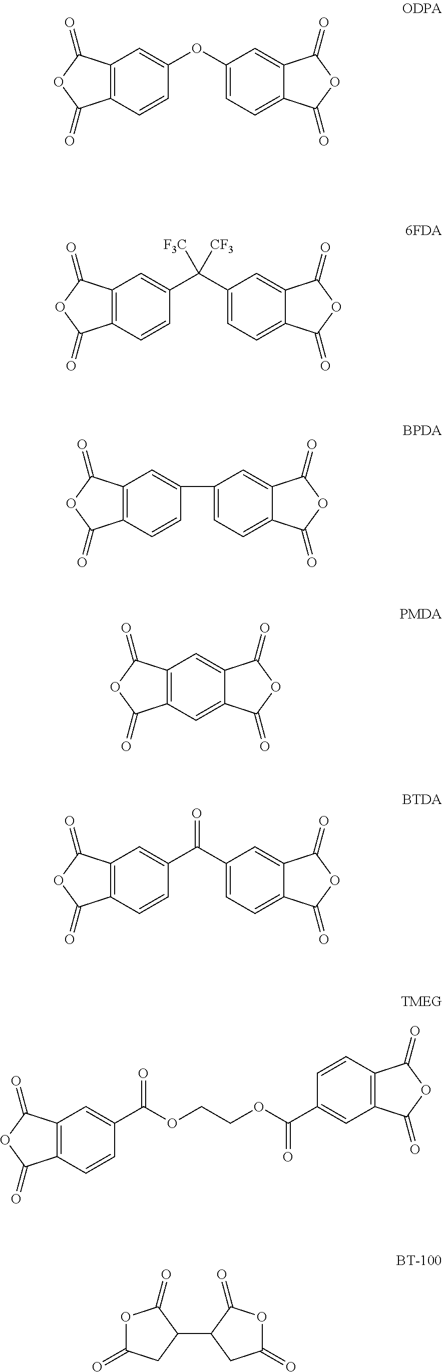

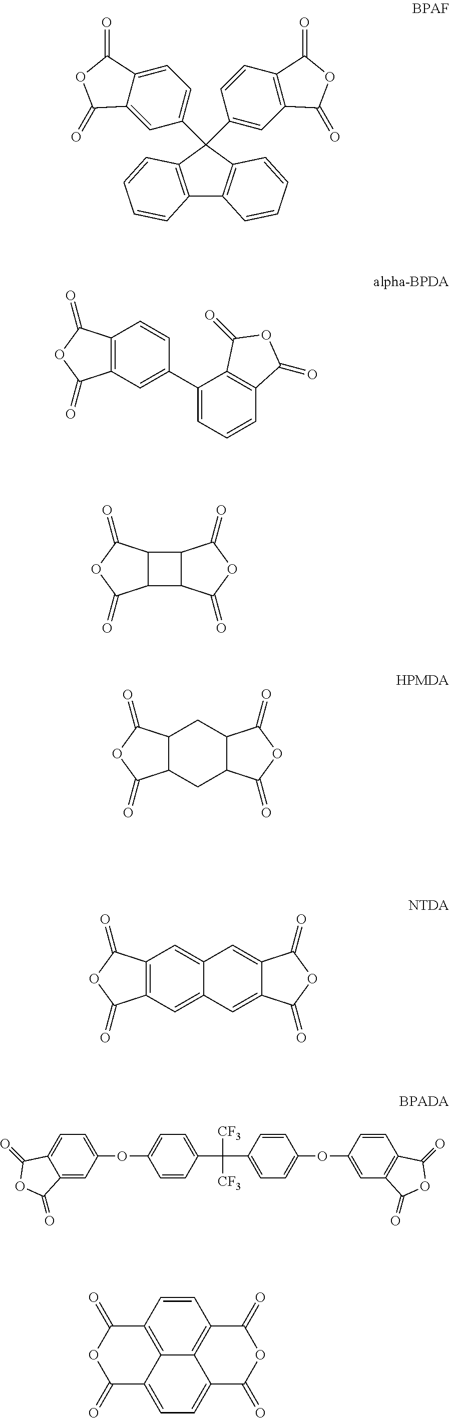

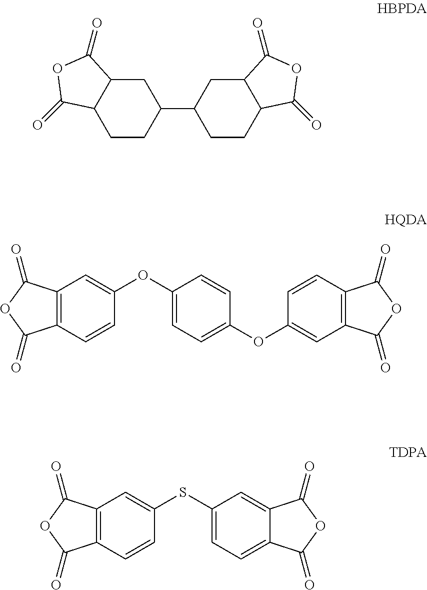 [SMILES: O=C1OC(=O)C2CC(C3CCC4C(=O)OC(=O)C4C3)CCC12 ; O=C1OC(=O)c2cc(Oc3ccc(Oc4ccc5c(c4)C(=O)OC5=O)cc3)ccc21 ; O=C1OC(=O)c2cc(Sc3ccc4c(c3)C(=O)OC4=O)ccc21]

In one embodiment of the present specification, Ra or Rb is the structure represented by Chemical Formula a or the structure represented by Chemical Formula b, and the structure represented by Chemical Formula a or the structure represented by Chemical Formula b is in 10 mol % to 70 mol % with respect to a total number of moles of —OH included in the polyimide resin. Preferably, the structure represented by Chemical Formula a or the structure represented by Chemical Formula b is in 15 mol % to 45 mol % with respect to a total number of moles of —OH included in the polyimide resin. When the structure represented by Chemical Formula a or the structure represented by Chemical Formula b is in less than 10 mol % with respect to a total number of moles of —OH included in the polyimide resin, the number of OH protected by the protection group is small and the number of OH not protected by the protection group is relatively large, which may reduce a residual film rate. In addition, when the structure represented by Chemical Formula a or the structure represented by Chemical Formula b is in greater than 70 mol % with respect to a total number of moles of —OH included in the polyimide resin, the number of OH protected by the protection group is large and the number of OH not protected by the protection group is relatively small, which may reduce sensitivity. Accordingly, when comprehensively considering developability, residual film rate, sensitivity and the like, the structure represented by Chemical Formula a or the structure represented by Chemical Formula b is preferably in 15 mol % to 45 mol % with respect to a total number of moles of —OH included in the polyimide resin.

In one embodiment of the present specification, the polyimide resin may have a weight average molecular weight of 1,000 g/mol to 70,000 g/mol, and more preferably 3,000 g/mol to 50,000 g/mol. When the polyimide resin has a weight average molecular weight of less than 1,000 g/mol, the produced insulating film may become brittle and have decreased adhesive strength. In addition, the polyimide resin having a weight average molecular weight of greater than 70,000 g/mol is not preferred since development fails to occur due to reduced sensitivity, or scum may remain.

The weight average molecular weight is one of average molecular weights for which molecular weights are not uniform and a molecular weight of a certain polymer material is used as a reference, and is a value obtained by averaging molecular weights of component molecular species of a polymer compound having molecular weight distribution by a weight fraction.

The weight average molecular weight may be measured using a gel permeation chromatography (GPC) method.

One embodiment of the present specification provides a positive-type photosensitive resin composition including a binder resin including the polyimide resin; a photoacid generator; a crosslinking agent; a surfactant; and a solvent.

In one embodiment of the present specification, the positive-type photosensitive resin composition includes, based on 100 parts by weight of the binder resin including the polyimide resin, the photoacid generator in 1 parts by weight to 40 parts by weight: the crosslinking agent in 5 parts by weight to 50 parts by weight; the surfactant in 0.05 parts by weight to 5 parts by weight; and the solvent in 50 parts by weight to 500 parts by weight.

When each of the constituents is included in the positive-type photosensitive resin composition in the above-described parts by weight range, sensitivity and properties are enhanced even with a small amount of the photoacid generator, and substrate adhesive strength is enhanced.

The photoacid generator is for using the positive-type photosensitive resin composition according to the present specification as a chemical amplified composition, and by effectively controlling an acid diffusion length, pattern resolution and the like may be enhanced. As the photoacid generator, common photoacid generators may be used without limit, and preferably, ionic photoacid generators such as a sulfonium salt and an iodonium salt, sulfonyldiazomethane-based, N-sulfonyloxyimide-based, benzoin sulfonate-based, nitrobenzylsulfonate-based, sulfone-based, glyoxime-based, triazine-based and the like may be used.

The sulfonium salt is a salt of a sulfonium cation and a sulfonate (sulfonic acid anion), and as the sulfonium cation, triphenolsulfonium, (4-tert-butoxyphenyl)diphenylsulfonium, bis(4-tert-butoxyphenyl)phenylsulfonium, 4-methylphenyldiphenylsulfonium, tris(4-methylphenylsulfonium), 4-tert-butylphenyldiphenylsulfonium, tris(4-tert-butylphenyl)sulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, dimethyl-2-naphthyldiphenylsulfonium, dimethyl-2-naphthylsulfonium, 4-hydroxyphenyldimethylsulfonium, 4-methoxyphenyldimethylsulfonium, trimethylsulfonium, diphenylmethylsulfonium, methyl-2-oxopropylphenylsulfonium, 2-oxocyclohexylcyclohexylmethylsulfonium, trinaphthylsulfonium and tribenzylsulfonium and the like may be included, and as the sulfonate, trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, methanesulfonate and the like may be included.

The iodonium salt is a salt of an iodonium cation and a sulfonate, and as the iodonium cation, diphenyliodonium, bis(4-tert-butylphenyl)iodonium, 4-tert-butoxyphenylphenyliodonium, 4-methoxyphenylphenyliodonium and the like may be included.

As the sulfonyldiazomethane-based photoacid generator, bissulfonyldiazomethane such as bis(ethylsulfonyl)diazomethane, bis(1-methylpropylsulfonyl)diazomethane, bis(2-methylpropylsulfonyl)diazomethane, bis(1,1-dimethylethylsulfonyl)diazomethane, bis(cyclohexylsulfonyl)diazomethane, bis(perfluoroisopropylsulfonyl)diazomethane, bis(phenylsulfonyl)diazomethane, bis(4-methylphenylsulfonyl)diazomethane, bis(2,4-dimethylphenylsulfonyl)diazomethane and bis(2-naphthylsulfonyl)diazomethane, sulfonylcarbonyldiazomethane such as 4-methylphenylsulfonylbenzoyldiazomethane, tert-butylcarbonyl-4-methylphenylsulfonyldiazomethane, 2-naphthylsulfonylbenzoyldiazomethane, 4-methylphenylsulfonyl-2-naphthoyldiazomethane, methylsulfonylbenzoyldiazomethane and tert-butoxycarbonyl-4-methylphenylsulfonyldiazomethane, and the like may be included.

As the N-sulfonyloxyimide-based photoacid generator, succinimide, naphthalenedicarboxylic imide, phthalimide, cyclohexyldicarboxylic imide, 5-norbornene-2,3-dicarboxylic imide, 7-oxabicyclo[2,2,1]-5-heptene-2,3-dicarboxylic imide, trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, methanesulfonate and the like may be included.

As the benzoin sulfonate-based photoacid generator, benzoin tosylate, benzoin mesylate, benzoin butanesulfonate and the like may be included, and as the nitrobenzylsulfonate-based photoacid generator, 2,4-dinitrobenzylsulfonate, 2-nitrobenzylsulfonate, 2,6-dinitrobenzylsulfonate, a compound obtained by substituting a nitro group of benzyl with a trifluoromethyl group, and the like may be included. As the sulfone-based photoacid generator, bis(phenylsulfonyl)methane, bis(4-methylphenylsulfonyl)methane, bis(2-naphthylsulfonyl)methane, 2,2-bis(phenylsulfonyl)propane, 2,2-bis(4-methylphenylsulfonyl)propane, 2,2-bis(2-naphthylsulfonyl)propane, 2-methyl-2-(p-toluenesulfonyl)propioneon, 2-(cyclohexylcarbonyl)-2-(p-toluenesulfonyl)propane, 2,4-dimethyl-2-(p-toluenesulfonyl)pentan-3-one and the like may be included.

As the glyoxime-based photoacid generator, bis-o-(p-toluenesulfonyl)-α-dimethylglyoxime, bis-o-(p-toluenesulfonyl)-α-dimethylglyoxime, bis-o-(p-toluenesulfonyl)-α-dicyclohexylglyoxime, bis-o-(p-toluenesulfonyl)-2,3-pentanedione glyoxime, bis-o-(p-toluenesulfonyl)-2-methyl-3,4-pentanedione glyoxime, bis-o-(n-butanesulfonyl)-α-dimethylglyoxime, bis-o-(n-butanesulfonyl)-α-dimethylglyoxime, bis-o-(n-butanesulfonyl)-α-dicyclohexylglyoxime, bis-o-(n-butanesulfonyl)-2,3-pentanedione glyoxime, bis-o-(n-butanesulfonyl)-2-methyl-3,4-pentanedione glyoxime, bis-o-(methanesulfonyl)-α-dimethylglyoxime, bis-o-(trifluoromethanesulfonyl)-α-dimethylglyoxime, bis-o-(1,1,1-trifluoroethanesulfonyl)-α-dimethylglyoxime, bis-o-(tert-butanesulfonyl)-α-dimethylglyoxime, bis-o-(perfluorooctanesulfonyl)-α-dimethylglyoxime, bis-o-(cyclohexylsulfonyl)-α-dimethylglyoxime, bis-o-(benzenesulfonyl)-α-dimethylglyoxime, bis-o-(p-fluorobenzenesulfonyl)-α-dimethylglyoxime, bis-o-(p-tert-butylbenzenesulfonyl)-α-dimethylglyoxime, bis-o-(xylenesulfonyl)-α-dimethylglyoxime, bis-o-(camphorsulfonyl)-α-dimethylglyoxime and the like may be included.

The crosslinking agent is not particularly limited, and those used in the art may be used without limit. Examples of the crosslinking agent may include 2-[[4-[2-[4-[1,1-bis[4-(oxiran-2-ylmethoxy)phenyl]ethyl]phenyl]propan-2-yl]phenoxy]methyl]oxirane, 4,4′-methylenebis(N,N-bis(oxiran-2-ylmethyl)aniline), YD-127, YD-128, YD-129, YDF-170, YDF-175 and YDF-180 of Kukdo Chemical Co., Ltd., and the like.

The surfactant is a silicone-based surfactant or a fluorine-based surfactant. Specifically, as the silicone-based surfactant, BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341v344, BYK-345v346, BYK-348, BYK-354, BYK-355, BYK-356, BYK-358, BYK-361, BYK-370, BYK-371, BYK-375, BYK-380, BYK-390 and the like of BYK-Chemie GmbH may be used, and as the fluorine-based surfactant, F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF1132, TF1027SF, TF-1441, TF-1442 and the like of DIC (DaiNippon Ink & Chemicals) may be used, however, the silicone-based surfactant and the fluorine-based surfactant are not limited thereto.

As the solvent, compounds known to enable formation of a photosensitive resin composition in the art may be used without particular limit. Nonlimiting examples of the solvent may include one or more types of compounds selected from the group consisting of ester-based, ether-based, ketone-based, aromatic hydrocarbon-based and sulfoxide-based.

The ester-based solvent may be ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, gamma-butyrolactone, epsilon-caprolactone, delta-valerolactone, oxyalkyl acetate (example: oxymethyl acetate, oxyethyl acetate, oxybutyl acetate (for example, methoxymethyl acetate, methoxyethyl acetate, methoxybutyl acetate, ethoxymethyl acetate, ethoxyethyl acetate and the like)), 3-oxypropionic acid alkyl esters (example: 3-oxymethyl propionate, 3-oxyethyl propionate (for example, 3-methoxymethyl propionate, 3-methoxyethyl propionate, 3-ethoxymethyl propionate, 3-ethoxyethyl propionate and the like)), 2-oxypropionic acid alkyl esters (example: 2-oxymethyl propionate, 2-oxyethyl propionate, 2-oxypropyl propionate (for example, 2-methoxymethyl propionate, 2-methoxyethyl propionate, 2-methoxypropyl propionate, 2-ethoxymethyl propionate, 2-ethoxyethyl propionate)), 2-oxy-2-methylmethyl propionate and 2-oxy-2-methylethyl propionate (for example, 2-methoxy-2-methylmethyl propionate, 2-ethoxy-2-methylethyl propionate and the like), methyl pyruvate, ethyl pyruvate, propyl pyruvate, acetomethyl acetate, acetoethyl acetate, 2-oxomethyl butyrate, 2-oxoethyl butyrate or the like.

The ether-based solvent may be diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate or the like.

The ketone-based solvent may be methyl ethyl ketone, cyclohexanone, cyclopentanone, 2-heptanone, 3-heptanone, N-methyl-2-pyrrolidone or the like.

The aromatic hydrocarbon-based solvent may be toluene, xylene, anisole, limonene or the like.

The sulfoxide-based solvent may be dimethyl sulfoxide or the like.

One embodiment of the present specification provides an insulating film including the positive-type photosensitive resin composition or a cured material thereof.

The insulating film may include the positive-type photosensitive resin composition as it is.

The insulating film may include a cured material of the positive-type photosensitive resin composition.

A light source for curing the photosensitive resin composition according to the present specification may include, for example, a mercury vapor arc, a carbon arc, a Xe arc, which emit light with a wavelength of 250 nm to 450 nm, and the like, but is not limited thereto.

After curing the positive-type photosensitive resin composition, heat treatment may be further conducted on the insulating film as necessary.

The heat treatment may be conducted using a heating means such as a hot plate, a hot air circulation furnace or an infrared furnace, and may be conducted at a temperature of 180° C. to 250° C., or 190° C. to 220° C.

The insulating film exhibits excellent chemical resistance and mechanical properties, and may be preferably used as an insulating film of a semiconductor device, an interlayer insulating film for a redistribution layer or the like. In addition, the insulation may be used in a photoresist, an etching resist, a solder top resistor the like.

The insulating film may include a support or a substrate.

The support or the substrate is not particularly limited, and those known in the art may be used. For example, substrates for electronic components, or those having a predetermined wiring pattern formed thereon may be included as an example. Examples of the substrate may include substrates made of metals such as silicon, silicon nitride, titanium, tantalum, palladium, tungsten titanate, copper, chromium, iron, aluminum, gold and nickel, glass substrates and the like. Examples of the material of the wiring pattern may include copper, solder, chromium, aluminum, nickel, gold and the like, but are not limited thereto. Preferably, the support or the substrate may be a silicon wafer.

The coating method is not particularly limited, however, a spray method, a roll coating method, a spin coating method and the like may be used, and a spin coating method is generally used widely. In addition, after forming the coating film, the residual solvent may be partially removed under vacuum in some cases.

In the present specification, the insulating film may have a thickness of 1 μm to 100 μm. When satisfying the thickness range of the insulating film, an insulating film having excellent chemical resistance and mechanical properties aimed in the present specification may be obtained. The thickness of the insulating film may be measured using a scanning electron microscope (SEM).

One embodiment of the present specification provides a semiconductor device including the insulating film.

Various components commonly used in the art may be further included in addition to the insulating film to manufacture the semiconductor device.

Hereinafter, the present specification will be described in detail with reference to examples in order to specifically describe the present specification. However, the examples according to the present specification may be modified to various other forms, and the scope of the present specification is not to be construed as being limited to the examples described below. The examples of the present specification are provided in order to more fully describe the present specification to those having average knowledge in the art.

### EXAMPLE

### Polymerization Example 1

After dissolving 2,2-bis(3-amino-4-hydroxyphenyl)hexafluoropropane (1 eq.), polyetheramine (D-400, Jeffamine) (0.25 eq.), 4,4′-oxydiphthalic anhydride (1.35 eq.) and 3-aminophenol (0.16 eq.) in PGMEA (propylene glycol methyl ether acetate) under the N₂ atmosphere, toluene was introduced to the reaction material at 150° C., and the result was reacted overnight at 180° C. after connected to a dean-stark. After the reaction, toluene of the dean-stark was removed, and the result was PGMEA substituted several times to remove residual toluene. The reaction was terminated after identifying the residual monomer by NMR, and Polymer 1 of the following structural formula was prepared. When measuring the molecular weight using gel permeation chromatography (GPC), the weight average molecular weight was identified to be 17,000 g/mol.

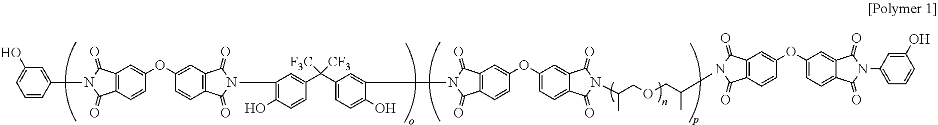

In Polymer 1,

n, o and p are values enabling the polymer to have a weight average molecular weight of 17,000 g/mol,

n is a real number of 2 to 15,

o is a real number of 5 to 40, and

p is a real number of 2 to 15.

### Polymerization Example 2

Polymer 2 was prepared in the same manner as in Polymerization Example 1 except that poly(1,4-butanediol)bis(4-aminobenzoate) was used instead of polyetheramine (D-400, Jeffamine). When measuring the molecular weight using gel permeation chromatography (GPC), the weight average molecular weight was identified to be 18,000 g/mol.

### Polymerization Example 3

Polymer 3 was prepared in the same manner as in Polymerization Example 1 except that polyetheramine (ED-600, Jeffamine) was used instead of polyetheramine (D-400, Jeffamine). When measuring the molecular weight using gel permeation chromatography (GPC), the weight average molecular weight was identified to be 19,000 g/mol.

### Polymerization Example 4

After dissolving 2,2-bis(3-amino-4-hydroxyphenyl)hexafluoropropane (1 eq.), 4,4′-oxydiphthalic anhydride (1.1 eq.) and 3-aminophenol (0.13 eq.) in PGMEA under the N₂ atmosphere, toluene was introduced to the reaction material at 150° C., and the result was reacted overnight at 180° C. after connected to a dean-stark. After the reaction, toluene of the dean-stark was removed, and the result was PGMEA substituted several times to remove residual toluene. The reaction was terminated after identifying the residual monomer by NMR, and Polymer 4 was prepared. When measuring the molecular weight using gel permeation chromatography (GPC), the weight average molecular weight was identified to be 18,000 g/mol.

### Synthesis Example 1

To Polymer 1 prepared in Polymerization Example 1, pyridinium p-toluenesulfonate (0.0038 eq.) was introduced with respect to OH of the polyimide, and after setting up an ice bath, ethyl vinyl ether (0.35 eq.) diluted in PGMEA was slowly dropped thereto at 0° C. The result was reacted overnight at 25° C., and the reaction was terminated when ethyl vinyl ether disappeared by NMR. After the reaction was finished, the result was extracted three times with ethyl acetate and water, and then the solvent was removed using a rotary evaporator. The result was dissolved again in acetone, and precipitated and filtered using hexane to obtain white solids.

Total OH of Polymer 1 was calculated by comparing with the introduced amount as the total sum of the area of the aromatic ring of the polymer appearing at 7 ppm or higher on NMR, and the ratio of acetal substitution was identified as the area of the peak (1H) appearing near 5 ppm with respect to the total OH. It was identified that the polymer was substituted with acetal by 25 mol %. When measuring the molecular weight using gel permeation chromatography (GPC), the weight average molecular weight was identified to be 20,000 g/mol. The structure of the polymer according to Synthesis Example 1 is as follows.

### Polymer of Synthesis Example 1

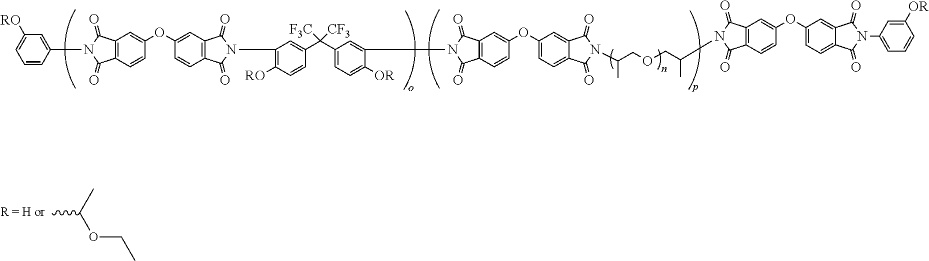

In the polymer of Synthesis Example 1,

n, o and p are values enabling the polymer to have a weight average molecular weight of 20,000 g/mol,

n is a real number of 2 to 15,

o is a real number of 5 to 40, and

p is a real number of 2 to 15.

### Synthesis Example 2

Synthesis was performed in the same manner as in Synthesis Example 1 except that Polymer 2 prepared in Polymerization Example 2 was used instead of Polymer 1. When measuring the molecular weight using gel permeation chromatography (GPC), the weight average molecular weight was identified to be 21,000 g/mol.

The structure of the polymer according to Synthesis Example 2 is as follows.

### Polymer of Synthesis Example 2

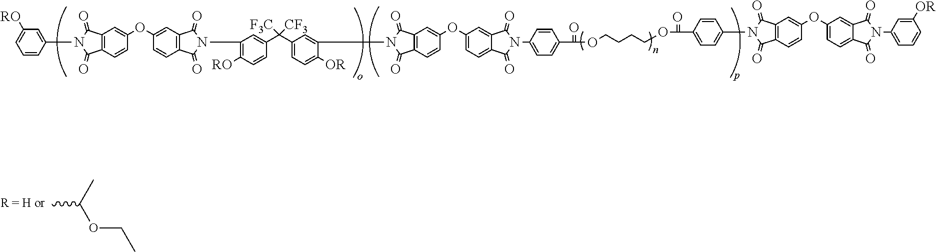

In the polymer of Synthesis Example 2,

n, o and p are values enabling the polymer to have a weight average molecular weight of 21,000 g/mol,

n is a real number of 2 to 15,

o is a real number of 5 to 40, and

p is a real number of 2 to 15.

### Synthesis Example 3

Synthesis was performed in the same manner as in Synthesis Example 1 except that Polymer 3 prepared in Polymerization Example 3 was used instead of Polymer 1. When measuring the molecular weight using gel permeation chromatography (GPC), the weight average molecular weight was identified to be 20,000 g/mol.

The structure of the polymer according to Synthesis Example 3 is as follows.

### Polymer of Synthesis Example 3

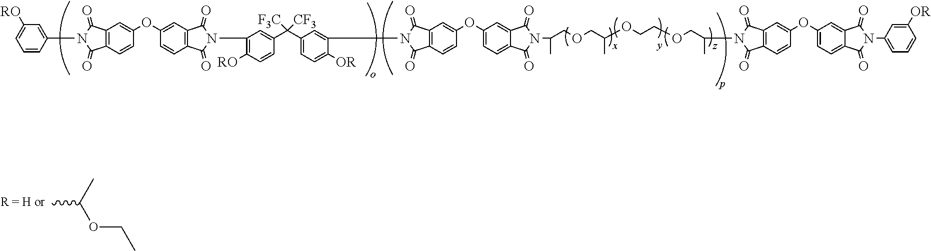

In the polymer of Synthesis Example 3,

x, y, z, o and p are values enabling the polymer to have a weight average molecular weight of 20,000 g/mol,

x, y and z are each a real number of 1 to 15,

o is a real number of 5 to 40, and

p is a real number of 2 to 15.

### Synthesis Example 4

Synthesis was performed in the same manner as in Synthesis Example 1 except that Polymer 4 prepared in Polymerization Example 4 was used instead of Polymer 1. When measuring the molecular weight using gel permeation chromatography (GPC), the weight average molecular weight was identified to be 20,000 g/mol.

The structure of the polymer according to Synthesis Example 4 is as follows.

### Polymer of Synthesis Example 4

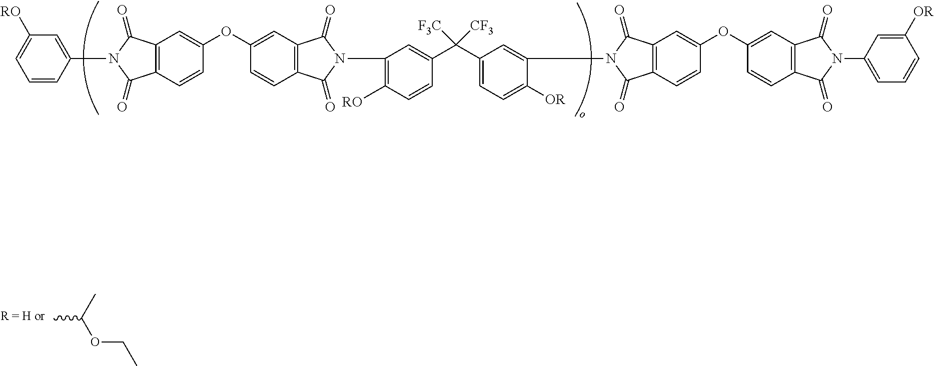

In the polymer of Synthesis Example 4,

o is a value enabling the polymer to have a weight average molecular weight of 20,000 g/mol, and

o is a real number of 5 to 40.

### Examples 1 to 3 and Comparative Examples 1 and 2

Positive-type photosensitive resin compositions were each prepared using components described in the following Table 1. Specifically, the positive-type photosensitive resin compositions were each prepared including, based on 100 parts by weight of the prepared polyimide resin, parts by weight of each component described in the following Table 1 and 200 parts by weight of a solvent.

TABLE 1

| | | | Photoacid | | Crosslinking | | | |
|---|---|---|---|---|---|---|---|---|
| | Polyimide Resin | | Generator | | Agent | | Surfactant | |
| | | Parts by | | Parts by | | Parts by | | Parts by |
| | Type | Weight | Type | Weight | Type | Weight | Type | Weight |
| Example 1 | Synthesis | 100 | B | 5 | D | 20 | E | 0.1 |
| | Example 1 | | | | | | | |
| Example 2 | Synthesis | 100 | B | 5 | D | 20 | E | 0.1 |
| | Example 2 | | | | | | | |
| Example 3 | Synthesis | 100 | B | 5 | D | 20 | E | 0.1 |
| | Example 3 | | | | | | | |
| Comparative | Polymerization | 100 | C | 15 | D | 20 | E | 0.1 |
| Example 1 | Example 1 | | | | | | | |
| Comparative | Synthesis | 100 | B | 5 | D | 20 | E | 0.1 |
| Example 2 | Exannple 4 | | | | | | | |

B: Irgacure PAG103 (BASF Corporation)
C: MIPHOTO PAC-TPA529 (Miwon Commercial Co., Ltd.)
D: 2-[[4-[2-[4-[1,1-bis[4-(oxiran-2-ylmethyoxy)phenyl]ethyl]phenyl]propan-2-yl]phenoxy]methyl]oxirane
E: BYK-307 (BYK-Chemie GmbH)

### Experimental Example

Each of the positive-type photosensitive resin compositions of the examples and the comparative examples was cured and evaluated under the condition as follows, and the results are described in the following Table 2. Specifically, the prepared positive-type photosensitive resin composition was coated on a substrate by spin coating. The result was soft baked, and then exposed at a proper exposure amount (sensitivity) using a stepper, and then, after conducting development using a developing solution (2.38 wt % TMAH sol.), post baked. In addition, in order to examine adhesion and elongation at break with a substrate, two sheets of substrates were additionally coated, soft baked, then frontside-exposed, and cured.

Resist evaluation condition: PrB 105° C./120 s, PB 180° C./2 hr, thickness 5 μm

Exposure: 300 mJ/cm² to 900 mJ/cm² i-line stepper

Develop: 23° C., 2.38 wt % TMAH (tetramethylammonium hydroxide) solution, dipping, DI water rinse

[Measurement of Sensitivity]

Sensitivity was identified by the previously proper exposure amount.

[Adhesion with Substrate]

The frontside-exposed cured layer on the substrate prepared above was cut into checkboards of 10 rowsx10 columns at a 2 mm interval using a knife edge, and after attaching and detaching with a cellophane tape, the number of peel-offs among the total 100 checkboards was counted to evaluate adhesion properties between the cured layer and the substrate.

◯: less than 15 were peeled off

Δ: 15 or more and less than 30 were peeled off

X: 30 or more were peeled off

[Measurement of Elongation at Break]

The frontside-exposed cured layer on the substrate prepared above was peeled from the substrate using an aqueous hydrogen fluoride solution to prepare a cured layer film. For the insulating film having a thickness of 5 m dried in an oven, elongation at break was measured using a UTM (universal testing machine) under the condition of room temperature and a 5 cm/min rate.

TABLE 2

| | Sensitivity | Adhesion with | Elongation at |
|---|---|---|---|
| | (mJ/cm²) | Substrate | Break (%) |
| Example 1 | 350 | ◯ | 45 |
| Example 2 | 400 | ◯ | 40 |
| Example 3 | 400 | ◯ | 40 |
| Comparative | 700 | Δ | 20 |
| Example 1 | | | |
| Comparative | 500 | X | 5 |
| Example 2 | | | |

As above, it was identified that the polyimide resin according to the present specification and the positive-type photosensitive resin composition including the same had superior elongation, sensitivity and substrate adhesive strength.

1. A polyimide resin comprising:
a structure represented by either of the following Chemical Formulae 1 and 2; and
a structure represented by any one of the following Chemical Formulae 3 to 5: 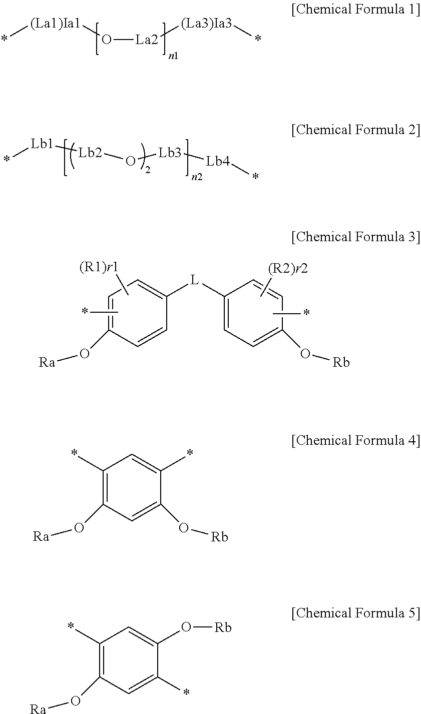
wherein, in the Chemical Formulae 1 to 5, [symbol]
means a site bonding to other substituents or repeating units;
La1 to La3, Lb1 to Lb4 and L are the same as or different from each other, and each independently a direct bond; a substituted or unsubstituted alkylene group; a substituted or unsubstituted arylene group; —SO₂—; —CO—; or —OCO—;
la1 is 1 or 2, and when la1 is 2, La1s are the same as or different from each other;
la3 is a real number of 0 to 2, and when la3 is 2, La3s are the same as or different from each other;
n1 and n2 are the same as or different from each other and each independently a real number of 1 to 150, and when n1 and n2 are each 2 or greater, structures in the parentheses are the same as or different from each other;
R1 and R2 are the same as or different from each other, and each independently hydrogen; or a substituted or unsubstituted alkyl group;
r1 and r2 are the same as or different from each other and each independently a real number of 0 to 3, and when r1 is 2 or greater, R1s are the same as or different from each other, and when r2 is 2 or greater, R2s are the same as or different from each other;
Ra and Rb are the same as or different from each other, and each independently hydrogen; or a structure represented by the following Chemical Formula a or a structure represented by the following Chemical Formula b; 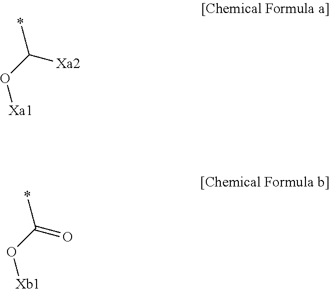
wherein, in the Chemical Formulae a and b, [symbol]
means a site linked to Chemical Formulae 3 to 5; and
Xa1, Xa2 and Xb1 are the same as or different from each other, and each independently a substituted or unsubstituted alkyl group; or a substituted or unsubstituted cycloalkyl group, or Xa1 and Xa2 bond to each other to form a substituted or unsubstituted ring, and
wherein, the structure represented by Chemical Formula a or the structure represented by Chemical Formula b is in 1 mol % or greater with respect to a total number of moles of —OH included in the polyimide resin.

2. The polyimide resin of claim 1, further comprising a structure represented by the following Chemical Formula E: 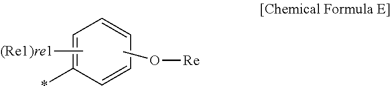
wherein, in the Chemical Formula E, [symbol]
means a site bonding to other substituents or repeating units;
Re1 is hydrogen; or a substituted or unsubstituted alkyl group;
re1 is a real number of 0 to 4, and when re1 is 2 or greater, Re1s are the same as or different from each other; and
Re is hydrogen; or the structure represented by Chemical Formula a or the structure represented by Chemical Formula b.

3. The polyimide resin of claim 1, wherein the Chemical Formula 1 is represented by any one of the following Chemical Formulae 1-1 to 1-3: 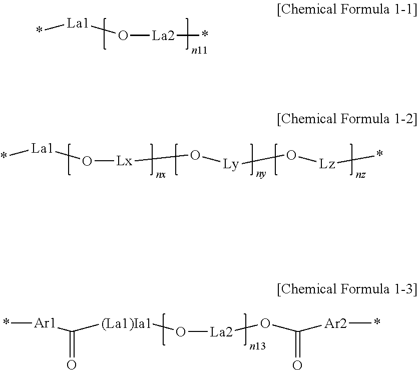
wherein, in the Chemical Formulae 1-1 to 1-3, [symbol]
means a site bonding to other substituents or repeating units;
La1, La2 and la1 have the same definitions as in Chemical Formula 1;
Lx, Ly and Lz are the same as or different from each other, and each independently a substituted or unsubstituted alkylene group;
Ar1 and Ar2 are the same as or different from each other, and each independently a substituted or unsubstituted arylene group;
n11 is a real number of 1 to 30;
nx, ny and nz are each independently a real number of 1 to 50; and
n13 is a real number of 1 to 30.

4. The polyimide resin of claim 1, further comprising any one of structures represented by the following Chemical Formulae A-1 to A-4: 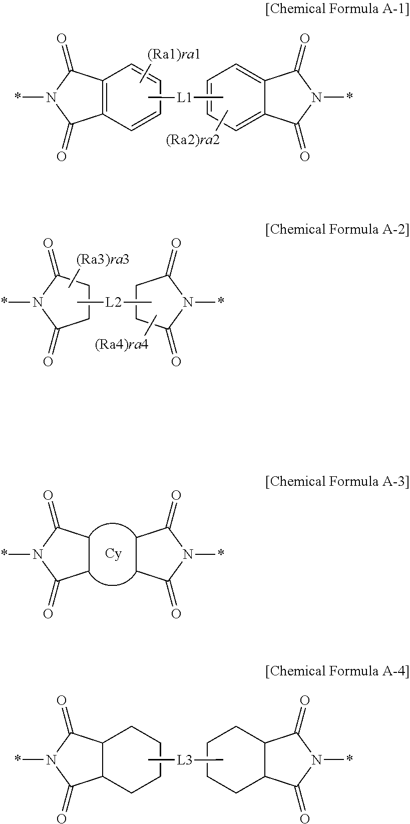
wherein, in Chemical Formulae A-1 to A-4, [symbol]
means a site bonding to other substituents or repeating units;
L1 to L3 are the same as or different from each other, and each independently a direct bond; a substituted or unsubstituted alkylene group; a substituted or unsubstituted arylene group; —O—; —CO—;
—S—; —COO-L′—OCO—; or —O—(L″)m-O—;
L′ and L″ are the same as or different from each other, and each independently a substituted or unsubstituted alkylene group; or a substituted or unsubstituted arylene group;
m is a real number of 1 to 5, and when m is 2 or greater, L″s are the same as or different from each other;
Ra1 to Ra4 are the same as or different from each other, and each independently hydrogen; or a substituted or unsubstituted alkyl group;
ra1 to ra4 are the same as or different from each other and each independently a real number of 0 to 3, and when ra1 is 2 or greater, Ra1s are the same as or different from each other, when ra2 is 2 or greater, Ra2s are the same as or different from each other, when ra3 is 2 or greater, Ra3s are the same as or different from each other, and when ra4 is 2 or greater, Ra4s are the same as or different from each other; and
Cy means a substituted or unsubstituted aliphatic ring or aromatic ring.

5. The polyimide resin of claim 1, wherein Ra or Rb is the structure represented by Chemical Formula a or the structure represented by Chemical Formula b; and
wherein the structure represented by Chemical Formula a or the structure represented by Chemical Formula b is in 10 mol % to 70 mol % with respect to a total number of moles of —OH included in the polyimide resin.

6. The polyimide resin of claim 1, wherein the polyimide resin has a weight average molecular weight of 1,000 g/mol to 70,000 g/mol.

7. A positive-type photosensitive resin composition comprising:
a binder resin including the polyimide resin of claim 1;
a photoacid generator;
a crosslinking agent;
a surfactant; and
a solvent.

8. The positive-type photosensitive resin composition of claim 7, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.

9. An insulating film comprising the positive-type photosensitive resin composition of claim 7 or a cured material thereof.

10. A semiconductor device comprising the insulating film of claim 9.

11. A positive-type photosensitive resin composition comprising:
a binder resin including the polyimide resin of claim 2;
a photoacid generator;
a crosslinking agent;
a surfactant; and
a solvent.

12. The positive-type photosensitive resin composition of claim 11, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.

13. A positive-type photosensitive resin composition comprising:
a binder resin including the polyimide resin of claim 3;
a photoacid generator;
a crosslinking agent;
a surfactant; and
a solvent.

14. The positive-type photosensitive resin composition of claim 13, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.

15. A positive-type photosensitive resin composition comprising:
a binder resin including the polyimide resin of claim 4;
a photoacid generator;
a crosslinking agent;
a surfactant; and
a solvent.

16. The positive-type photosensitive resin composition of claim 15, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.

17. A positive-type photosensitive resin composition comprising:
a binder resin including the polyimide resin of claim 5;
a photoacid generator;
a crosslinking agent;
a surfactant; and
a solvent.

18. The positive-type photosensitive resin composition of claim 17, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.

19. A positive-type photosensitive resin composition comprising:
a binder resin including the polyimide resin of claim 6;
a photoacid generator;
a crosslinking agent;
a surfactant; and
a solvent.

20. The positive-type photosensitive resin composition of claim 19, comprising:
the photoacid generator in 1 parts by weight to 40 parts by weight;
the crosslinking agent in 5 parts by weight to 50 parts by weight;
the surfactant in 0.05 parts by weight to 5 parts by weight; and
the solvent in 50 parts by weight to 500 parts by weight,
based on 100 parts by weight of the binder resin including the polyimide resin.
